(19) United States
(12) Patent Application Publication
(10) Pub. No.: US 2026/0122954 A1
(43) Pub. Date: Apr. 30, 2026

(54) SEMICONDUCTOR DEVICES

(71) Applicant: Samsung Electronics Co., Ltd., Suwon-si (KR)

(72) Inventors: Jun Heo, Suwon-si (KR); Juyoun Kim, Suwon-si (KR); Sewoung Oh, Suwon-si (KR); Minhyung Kang, Suwon-si (KR); Soohun Hong, Suwon-si (KR); Hyeongsu Kim, Suwon-si (KR); Giwoong Shin, Suwon-si (KR); Hyunki Yoon, Suwon-si (KR); Junhyeok Choi, Suwon-si (KR)

(21) Appl. No.: 19/241,684

(22) Filed: Jun. 18, 2025

(30) Foreign Application Priority Data
Oct. 30, 2024 (KR) 10-2024-0150514

(51) Int. Cl. H10D 30/00; H10D 30/01

(52) U.S. Cl. CPC H10D 30/508; H10D 30/0195; H10D 30/509

(57) ABSTRACT

A semiconductor device may include a gate structure, a plurality of channel patterns spaced apart from each other in a first direction, each of the plurality of channel patterns extending through the gate structure in a second direction substantially perpendicular to the first direction, a source/drain layer adjacent to the gate structure in the second direction, the source/drain layer contacting the plurality of channel patterns, a first spacer on a sidewall of the gate structure in the second direction and including an insulating material, and a second spacer on a sidewall of the first spacer in the second direction, the second spacer contacting the source/drain layer. The first spacer may include opposite edge portions in the first direction and a center portion in the first direction, and a width of the first spacer in the second direction may increase from the opposite edge portions toward the center portion.

### CROSS-REFERENCE TO RELATED APPLICATIONS

This application claims priority under 35 U.S.C. § 119 to Korean Patent Application No. 10-2024-0150514, filed on Oct. 30, 2024 in the Korean Intellectual Property Office, the disclosure of which is hereby incorporated by reference in its entirety.

### BACKGROUND OF THE INVENTION

Example embodiments of the present disclosure relate to semiconductor devices.

A semiconductor device may include a gate structure and source/drain layers disposed at opposite sides thereof. An inner spacer may be disposed on a sidewall of the gate structure to help reduce or prevent a leakage current that may occur between the gate structure and the source/drain layers.

### SUMMARY OF THE INVENTION

Example embodiments provide semiconductor devices having improved electrical characteristics.

According to some example embodiments, semiconductor devices are provided that include a gate structure, a plurality of channel patterns spaced apart from each other in a first direction, each of the plurality of channel patterns extending through the gate structure in a second direction substantially perpendicular to the first direction, a source/drain layer adjacent to the gate structure in the second direction, the source/drain layer contacting the plurality of channel patterns, a first spacer on a sidewall of the gate structure in the second direction and including an insulating material, and a second spacer on a sidewall of the first spacer in the second direction, the second spacer contacting the source/drain layer, wherein the first spacer includes opposite edge portions in the first direction and a center portion in the first direction, and wherein a width of the first spacer in the second direction increases from the opposite edge portions toward the center portion.

According to some example embodiments, semiconductor devices are provided that include a plurality of channel patterns each extending in a first direction and spaced apart from each other in a second direction substantially perpendicular to the first direction, a gate structure at least partially surrounding an upper surface, a lower surface and a sidewall of each of the plurality of channel patterns, a source/drain layer adjacent to the gate structure in the first direction, the source/drain layer contacting the plurality of channel patterns, and a first spacer and a second spacer sequentially stacked on a sidewall of the gate structure in the first direction, wherein the second spacer at least partially overlaps a first one of the plurality of channel patterns in the first direction.

According to some example embodiments, semiconductor devices are provided that include an active pattern on a substrate, the active pattern extending in a first direction substantially parallel to an upper surface of the substrate, a gate structure on the active pattern, the gate structure extending in a second direction substantially parallel to the upper surface of the substrate and crossing the first direction, a plurality of channel patterns spaced apart from each other in a vertical direction substantially perpendicular to the upper surface of the substrate, each of the plurality of channel patterns extending through the gate structure, a source/drain layer comprising a first epitaxial pattern adjacent to the gate structure in the first direction, the first epitaxial pattern including a first semiconductor material having a first impurity concentration, and a second epitaxial pattern contacting a sidewall of the first epitaxial pattern, the second epitaxial pattern including a second semiconductor material having a continuous crystal structure and having a second impurity concentration lower than the first impurity concentration, a first spacer on a sidewall of the gate structure in the first direction and including silicon nitride, and a second spacer on a sidewall of the first spacer in the first direction and including a semiconductor material.

According to some example embodiments, methods of manufacturing semiconductor devices are provided where a first opening may be formed through semiconductor patterns and sacrificial patterns, and the sacrificial patterns exposed by the first opening may be partially etched to form recesses on sidewalls of the sacrificial patterns. A first spacer including an insulating material and a second spacer including a semiconductor material may be formed in each of the recesses. A source/drain layer may be formed by an SEG process using the sidewalls of the semiconductor patterns and the sidewalls of the second spacers as a seed layer.

Thus, the crystal structure of the semiconductor material included in the source/drain layer may be continuous, so that the source/drain layer may have enhanced crystallinity. Accordingly, the resistance of the source/drain layer may be improved, and the semiconductor devices including the source/drain layer may have improved electrical characteristics.

### BRIEF DESCRIPTION OF THE DRAWINGS

FIGS. 1 to 6 are a plan view and cross-sectional views illustrating a semiconductor device in accordance with example embodiments.

FIGS. 7 to 26 are plan views and cross-sectional views illustrating a method of manufacturing a semiconductor device in accordance with example embodiments.

### DETAILED DESCRIPTION

The above and other aspects and features of semiconductor devices and methods of manufacturing the same in accordance with example embodiments will become readily understood from the detailed description hereinafter, with reference to the accompanying drawings. It will be understood that, although the terms “first,” “second,” and/or “third” may be used herein to describe various materials, layers (films), regions, electrodes, pads, patterns, structures and/or processes, these materials, layers (films), regions, electrodes, pads, patterns, structures and/or processes should not be limited by these terms. Rather, these terms are only used to distinguish one material, layer (film), region, electrode, pad, pattern, structure and/or process from another material, layer (film), region, electrode, pad, pattern, structure and/or process. Thus, a first material, layer (film), region, electrode, pad, pattern, structure and/or process discussed below could be termed a second or third material, layer (film), region, electrode, pad, pattern, structure and/or process without departing from the teachings of the present disclosure.

Hereinafter, in the specification (but not necessarily in the claims), two directions that are substantially perpendicular to each other among horizontal directions, which are substantially parallel to an upper surface of a substrate, may be referred to as first and second directions D1 and D2, respectively, and a vertical direction substantially perpendicular to the upper surface of the substrate may be referred to as a third direction D3. For example, the third direction D3 may be substantially perpendicular to each of the first and second directions D1 and D2. In example embodiments, the first and second directions D1 and D2 may be orthogonal to each other. Each of the first to third directions D1, D2 and D3 may represent not only a direction shown in the drawing, but also a reverse direction to the shown direction.

As used herein, the terms “comprises,” “comprising,” “includes,” “including,” “has,” “having” and any other variations thereof specify the presence of the stated features, steps, operations, elements, components, and/or groups but do not preclude the presence or addition of one or more other features, steps, operations, elements, components, and/or groups thereof. Further, as used herein, the term “and/or” includes any and all combinations of one or more of the associated listed items.

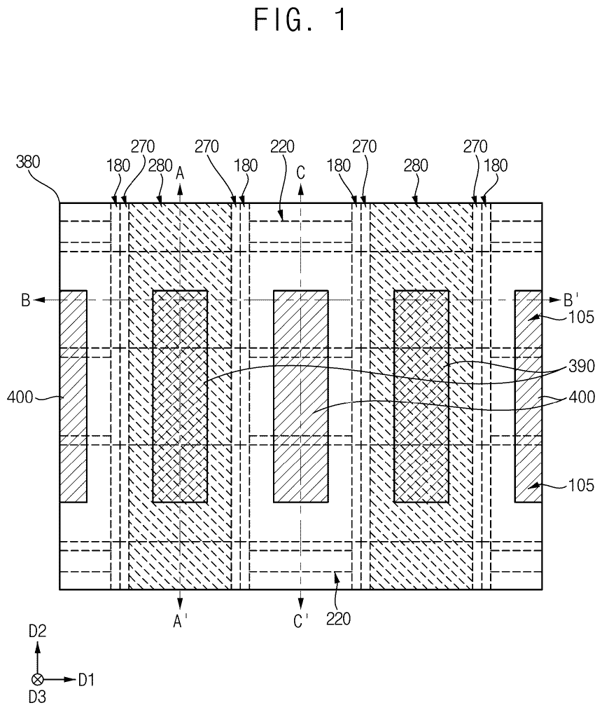

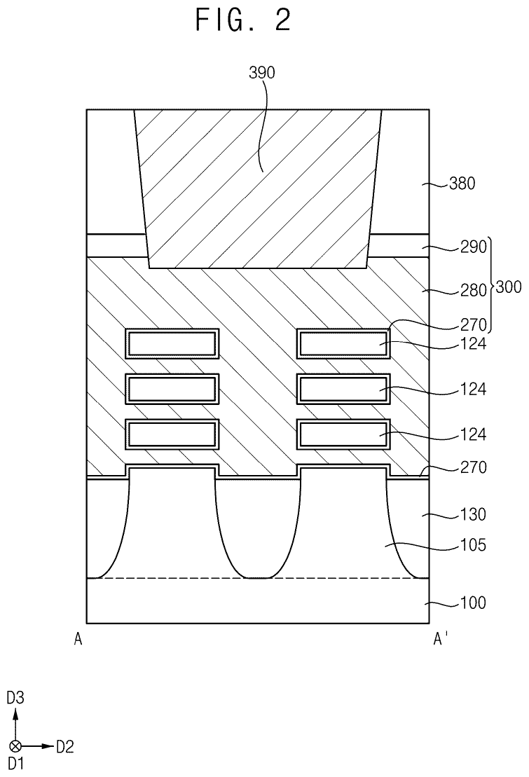

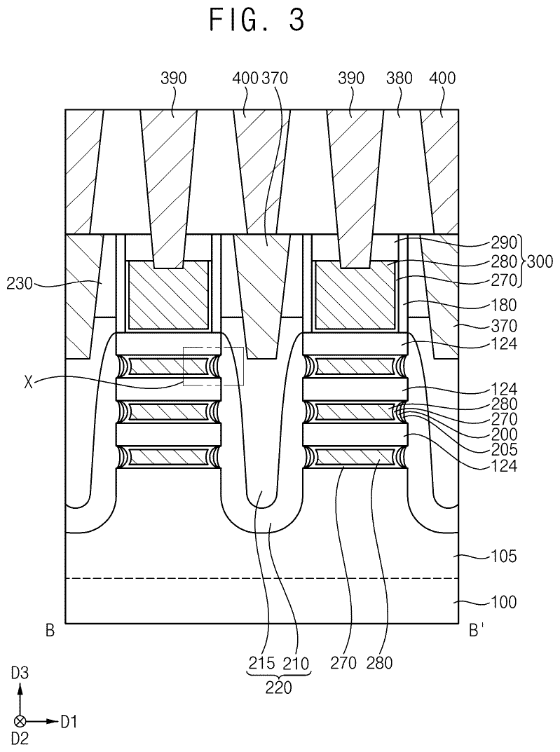

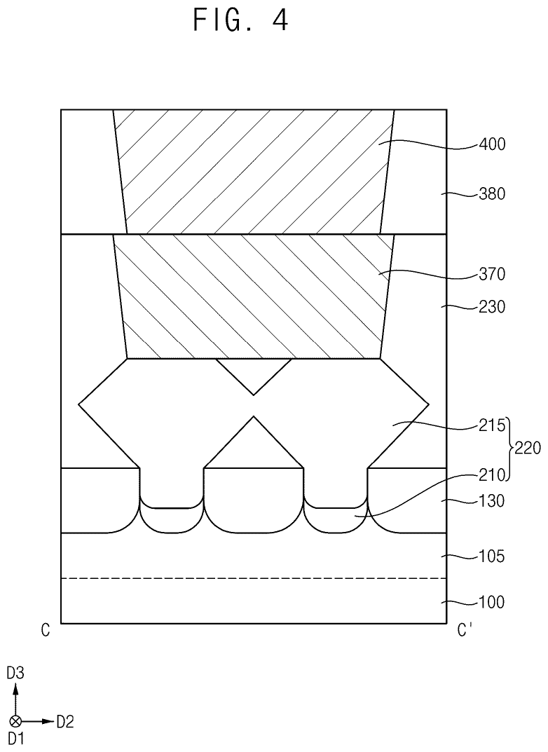

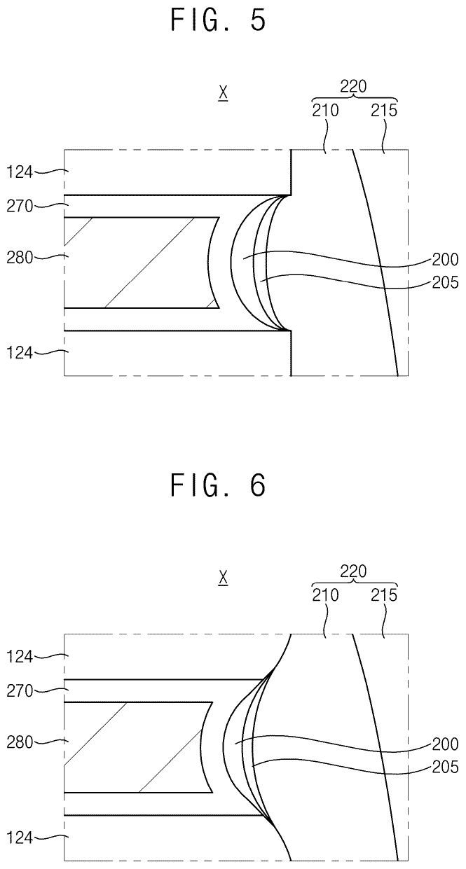

FIGS. 1 to 6 are a plan view and cross-sectional views illustrating a semiconductor device in accordance with example embodiments. Specifically, FIG. 1 is the plan view, and FIGS. 2 to 6 are the cross-sectional views. FIG. 2 is a cross-sectional view taken along line A-A′ of FIG. 1, FIG. 3 is a cross-sectional view taken along line B-B′ of FIG. 1, FIG. 4 is a cross-sectional view taken along line C-C′ of FIG. 1, and FIGS. 5 and 6 are enlarged cross-sectional views of a region X of FIG. 3.

Referring to FIGS. 1 to 6, the semiconductor device may include an active pattern 105, an isolation pattern 130, semiconductor patterns 124, first and second spacers 200 and 205, a gate spacer 180, a source/drain layer 220, a gate structure 300, first and second contact plugs 370 and 390, first and second insulating interlayers 230 and 380, and a via 400 on a substrate 100.

The substrate 100 may include a semiconductor material, e.g., silicon, germanium, silicon-germanium, etc., or III-V semiconductor compounds, e.g., GaP, GaAs, GaSb, etc. In some embodiments, the substrate 100 may include a silicon-on-insulator (SOI) substrate or a germanium-on-insulator (GOI) substrate.

The active pattern 105 may protrude upwardly from the substrate 100 (e.g., in the third direction D3), and a sidewall of the active pattern 105 may be covered by the isolation pattern 130. It will be understood that “an element A covers a surface of an element B” (or similar language) as used herein means that the element A is on the surface of the element B but does not necessarily mean that the element A covers the surface of the element B entirely.

In example embodiments, the active pattern 105 may extend in the first direction D1, and a plurality of active patterns 105 may be spaced apart from each other in the second direction D2.

In example embodiments, the isolation pattern 130 may extend in the first direction D1 between neighboring ones of the active patterns 105, and a plurality of isolation patterns 130 may be spaced apart from each other in the second direction D2.

The active pattern 105 may include a material substantially the same as that of the substrate 100, and the isolation pattern 130 may include an oxide, e.g., silicon oxide.

In example embodiments, a plurality of semiconductor patterns 124 may be formed at a plurality of levels, respectively, and may be spaced apart from each other in the third direction D3 from an upper surface of the active pattern 105. Each of the plurality of semiconductor patterns 124 may extend in the first direction D1 to a given length. FIGS. 2 and 3 show three semiconductor patterns 124 at three levels, respectively, however, the present disclosure is not limited thereto. In some other embodiments, more or less than three semiconductor patterns 124 may be on the upper surface of the active pattern 105.

Additionally, FIG. 3 shows two semiconductor patterns 124 spaced apart from each other in the first direction D1 at each level on the active pattern 105 extending in the first direction D1, however, the present disclosure is limited thereto.

In example embodiments, the semiconductor pattern 124 may be a nano-sheet or nano-wire including a semiconductor material, e.g., silicon, germanium, etc. In example embodiments, the semiconductor pattern 124 may serve as a channel in a transistor, and thus may also be referred to as a channel or a channel pattern.

The gate structure 300 may extend in the second direction D2 on the active pattern 105 and the isolation pattern 130, and may include a gate insulation pattern 270, a gate electrode 280 and a capping pattern 290.

In example embodiments, the gate structure 300 may surround a central portion in the first direction D1 of each of the semiconductor patterns 124, and may cover lower and upper surfaces and opposite sidewalls in the second direction D2 of each of the semiconductor patterns 124. In other words, the gate structure 300 may at least partially surround an upper surface, a lower surface and opposite sidewalls of each of the semiconductor patterns 124. For example, each of the semiconductor patterns 124 may extend through the gate structure 300 (e.g., in the first direction D1). It will be understood that “an element A surrounds an element B” (or similar language) as used herein means that the element A is at least partially around the element B but does not necessarily mean that the element A completely encloses the element B.

In example embodiments, the gate insulation pattern 270 may be disposed on a surface of each of the semiconductor patterns 124, upper surfaces of the active pattern 105 and the isolation pattern 130 and an inner sidewall of the gate spacer 180. The gate electrode 280 may extend in (e.g., may fill) a space between the semiconductor patterns 124 spaced apart from each other in the third direction D3, a space between the active pattern 105 and a lowermost one of the semiconductor patterns 124, and a space between the gate spacers 180 spaced apart from each other in the first direction D1 on an uppermost one of the semiconductor patterns 124. The capping pattern 290 may contact upper surfaces of the gate insulation pattern 270 and the gate electrode 280, and the inner sidewall of the gate spacer 180.

Hereinafter, a portion of the gate structure 300 disposed on the uppermost one of the semiconductor patterns 124 may be referred to as an upper portion, and a portion of the gate structure 300 below the upper portion, specifically a portion disposed between adjacent semiconductor patterns 124 in the third direction D3 and between the lowermost one of the semiconductor patterns 124 and the upper surface of the active pattern 105, may be referred to as a lower portion. In example embodiments, a plurality of lower portions of the gate structure 300 may be spaced apart from each other in the third direction D3 by the semiconductor patterns 124.

The gate insulation pattern 270 may include an oxide, e.g., silicon oxide. The gate electrode 280 may include a metal nitride, e.g., titanium nitride (TiN), titanium aluminum nitride (TiAlN), tantalum nitride (TaN), tantalum aluminum nitride (TaAlN), etc., a metal alloy, a metal carbide, a metal oxynitride, a metal carbonitride or a metal oxycarbonitride, e.g., titanium aluminum carbide (TiAlC), titanium aluminum oxynitride (TiAlON), titanium aluminum carbonitride (TiAlCN), titanium aluminum oxycarbonitride (TiAlOCN), etc., or a low-resistance metal, e.g., tungsten (W), aluminum (Al), copper (Cu), or tantalum (Ta). The capping pattern 290 may include an insulating nitride, e.g., silicon nitride.

The gate spacer 180 may be formed on each of opposite sidewalls in the first direction D1 of the upper portion of the gate structure 300. The gate spacer 180 may include an oxide, e.g., silicon oxide, or an insulating nitride, e.g., silicon nitride. The capping pattern 290 may include an insulating nitride, e.g., silicon nitride.

The first spacer 200 may be disposed on each of opposite sidewalls of the lower portion of the gate structure 300 in the first direction D1, and the second spacer 205 may be disposed on an outer sidewall of the first spacer 200 in the first direction D1. In other words, the first spacer 200 and the second spacer 205 may be sequentially stacked on a sidewall of the gate structure 300 (e.g., the sidewall of the lower portion of the gate structure 300) in the first direction D1. An inner sidewall of the first spacer 200 in the first direction D1 may contact the sidewall of the gate structure 300 in the first direction D1, and the outer sidewall of the first spacer 200 may contact an inner sidewall of the second spacer 205 in the first direction D1. For example, the second spacer 205 may contact the source/drain layer 220. A plurality of first spacers 200 may be spaced apart from each other in the third direction D3, and a plurality of second spacers 205 may be spaced apart from each other in the third direction D3. For example, the plurality of second spacers 205 may be respectively adjacent to the plurality of first spacers 200 (e.g., in the first direction D1).

The first spacer 200 may include an insulating material, e.g., silicon nitride, silicon oxide, etc., and the second spacer 205 may include a semiconductor material, e.g., silicon, silicon-germanium, etc. The semiconductor material may be an amorphous semiconductor material or a polycrystalline semiconductor material. In some embodiments, the second spacer 205 and the semiconductor patterns 124 may include substantially the same material.

In example embodiments, each of the first and second spacers 200 and 205 may have a convex shape toward the gate structure 300, and a cross-section in the third direction D3 of each of the first and second spacers 200 and 205 may have a shape of a crescent. That is, the inner and outer sidewalls of each of the first and second spacers 200 and 205 may have a convex shape toward the lower portion of the gate structure 300. For example, the inner and outer sidewalls of each of the first and second spacers 200 and 205 may be opposite to each other in the first direction D1. For example, in a cross-sectional view, each of the first and second spacers 200 and 205 may have a crescent shape that is convex toward the gate structure 300 (e.g., toward the lower portion of the gate structure 300). The inner sidewall of the first spacer 200 in the first direction D1 may have a first curvature, the outer sidewall of the first spacer 200 in the first direction D1 may have a second curvature lower than (i.e., smaller than) the first curvature, and the outer sidewall of the second spacer 205 in the first direction D1 may have a third curvature lower than the second curvature. In other words, a curvature of the inner sidewall of the first spacer 200 may be greater than a curvature of the outer sidewall of the first spacer 200. For example, the second spacer 205 may be on the outer sidewall of the first spacer 200. The inner sidewall of the second spacer 205 may contact the outer sidewall of the first spacer 200, and the outer sidewall of the second spacer 205 may contact the source/drain layer 220. A maximum width of the first spacer 200 in the first direction D1 may be greater than a maximum width of the second spacer 205 in the first direction D1. In some embodiments, the first spacer 200 may include opposite edge portions in the third direction D3 and a center portion in the third direction D3, and a width of the first spacer 200 in the first direction D1 may increase when moving from each of the opposite edge portions toward the center portion of the first spacer 200 (e.g., see FIGS. 5 and 6). Similarly, in some embodiments, the second spacer 205 may include opposite edge portions in the third direction D3 and a center portion in the third direction D3, and a width of the second spacer 205 in the first direction D1 may increase when moving from each of the opposite edge portions toward the center portion of the second spacer 205 (e.g., see FIGS. 5 and 6).

In example embodiments, as illustrated in FIG. 5, each of the first and second spacers 200 and 205 may be disposed between the semiconductor patterns 124 adjacent to each other in the third direction D3, and between the upper surface of the lowermost one of the semiconductor patterns 124 and the active pattern 105, and may have a same thickness in the third direction D3 as a corresponding one of the lower portions of the gate structure 300. Each of the first and second spacers 200 and 205 may not overlap the semiconductor patterns 124 and the active pattern 105 in the first direction D1.

In other embodiments, as illustrated in FIG. 6, each of the first and second spacers 200 and 205 may have a thickness in the third direction D3 greater than the thickness in the third direction D3 of the corresponding one of the lower portions of the gate structure 300. Each of the first and second spacers 200 and 205 may overlap at least partially with an adjacent one of the semiconductor patterns 124 or active patterns 105 in the first direction D1. For example, an end portion of the first spacer 200 in the third direction D3 may contact an adjacent one of the semiconductor patterns 124 or active patterns 105. The end portion of the first spacer 200 in the third direction D3 may extend onto a sidewall of an adjacent one of the semiconductor patterns 124 or active patterns 105. As used herein, “an element A overlaps an element B in a direction X” (or similar language) means that there is at least one straight line that extends in the direction X and intersects both the elements A and B.

The source/drain layer 220 may include a first epitaxial pattern 210 and a second epitaxial pattern 215. The source/drain layer 220 may be disposed on a portion of the active pattern 105 adjacent to the gate structure 300, and may contact the outer sidewall of the second spacer 205 in the first direction D1 and a sidewall of the semiconductor patterns 124 in the first direction D1. For example, the source/drain layer 220 may be adjacent to the gate structure 300 (e.g., in the first direction D1) and may contact the semiconductor patterns 124. An upper portion of the source/drain layer 220 may partially contact a lower portion of an outer sidewall of the gate spacer 180.

In example embodiments, the second epitaxial pattern 215 may extend in the third direction D3 and may include an upper portion contacting the outer sidewall of the gate spacer 180 and a lower portion contacting an inner sidewall of the first epitaxial pattern 210. The first epitaxial pattern 210 may be on (e.g., may cover and/or overlap) a sidewall and a lower surface of the lower portion of the second epitaxial pattern 215. For example, the first epitaxial pattern 210 may contact the sidewall of the second epitaxial pattern 215. The first and second epitaxial patterns 210 and 215 may be adjacent to the gate structure 300 (e.g., in the first direction D1).

The first epitaxial pattern 210 may include a protrusion protruding in the first direction D1 toward the gate structure 300 disposed on an outer sidewall of the first epitaxial pattern 210. For example, the protrusion of the first epitaxial pattern 210 may be on an outer sidewall of the second spacer 205. A sum of widths in the first direction D1 of the lower portion of the gate structure 300 and the first and second spacers 200 and 205 on each of the opposite sidewalls of the lower portion of the gate structure 300 in the first direction D1 may be smaller than a width in the first direction D1 of each of the semiconductor patterns 124, and thus the lower portion of the gate structure 300 and the first and second spacers 200 and 205 on each of the opposite sidewalls of the lower portion of the gate structure 300 in the first direction D1 may have a concave shape with respect to the sidewalls of the semiconductor patterns 124 disposed below and above the lower portion of the gate structure 300 and the first and second spacers 200 and 205. The protrusion of the first epitaxial pattern 210 may protrude toward the concave outer sidewall of the second spacer 205, and as a plurality of semiconductor patterns 124 are spaced apart from each other in the third direction D3, a plurality of protrusions may also be spaced apart from each other in the third direction D3, correspondingly. That is, the source/drain layer 220 (e.g., the first epitaxial pattern 210 of the source/drain layer 220) may include protrusions that each protrude in the first direction D1 and are spaced apart from each other in the third direction D3, and the protrusions of the source/drain layer 220 may respectively contact sidewalls of the plurality of second spacers 205.

In example embodiments, the first epitaxial pattern 210 may include single crystalline silicon-germanium or single crystalline silicon-germanium doped with p-type impurities, e.g., boron (B), aluminum (Al), etc., and the second epitaxial pattern 215 may include single crystalline silicon-germanium doped with p-type impurities, e.g., boron (B), aluminum (Al), etc., and thus may serve as a source/drain layer of a PMOS transistor. The source/drain layer 220 may have a cross-section taken along the second direction D2 having, e.g., a pentagon-like shape. That is, in a cross-sectional view (e.g., taken along the second direction D2), the source/drain layer 220 may have a pentagon-like shape. A concentration of germanium included in the second epitaxial pattern 215 may be higher than a concentration of germanium included in the first epitaxial pattern 210, and a concentration of p-type impurities doped in the second epitaxial pattern 215 may be higher than a concentration of p-type impurities doped in the first epitaxial pattern 210. In other words, the second epitaxial pattern 215 may include a second semiconductor material (e.g., silicon-germanium) having a second impurity concentration (e.g., of p-type impurities), and the first epitaxial pattern 210 may include a first semiconductor material (e.g., silicon-germanium) having a first impurity concentration (e.g., of p-type impurities) lower than the second impurity concentration.

In other embodiments, the first epitaxial pattern 210 may include single crystalline silicon or single crystalline silicon doped with n-type impurities, e.g., phosphorus (P), arsenic (As), etc., and the second epitaxial pattern 215 may include single crystalline silicon doped with n-type impurities, e.g., phosphorus (P), arsenic (As), etc., and thus may serve as a source/drain layer of an NMOS transistor. The source/drain layer 220 may have a cross-section taken along the second direction D2 having a shape of, e.g., a square with rounded corners or a circle. A concentration of the n-type impurities doped in the second epitaxial pattern 215 may be higher than a concentration of the n-type impurities doped in the first epitaxial pattern 210. In other words, the second epitaxial pattern 215 may include a second semiconductor material (e.g., silicon) having a second impurity concentration (e.g., of n-type impurities), and the first epitaxial pattern 210 may include a first semiconductor material (e.g., silicon) having a first impurity concentration (e.g., of n-type impurities) lower than the second impurity concentration.

The first insulating interlayer 230 may be disposed on the source/drain layer 220, and may be on (e.g., may cover and/or overlap) the outer sidewall of the gate spacer 180 on the sidewall of the gate structure 300. The first contact plug 370 may extend into (e.g., may extend through) the first insulating interlayer 230, and may contact and be electrically connected to the upper portion of the source/drain layer 220, that is, an upper portion of the second epitaxial pattern 215. The second insulating interlayer 380 may be disposed on the first insulating interlayer 230, the gate structure 300, the gate spacer 180 and the first contact plug 370.

Each of the first and second insulating interlayers 230 and 380 may include an insulating material, e.g., silicon oxycarbide (SiOC), silicon oxide (SiO₂), silicon nitride (SiN), silicon oxynitride (SiON), silicon carbonitride (SiCN), silicon oxycarbonitride (SiOCN), etc.

The second contact plug 390 may extend into (e.g., may extend through) the second insulating interlayer 380 and the capping pattern 290, and may contact an upper surface of the gate electrode 280. The via 400 may extend into (e.g., may extend through) the second insulating interlayer 380, and may contact an upper surface of the first contact plug 370. Each of the first contact plug 370, the second contact plug 390 and the via 400 may include, e.g., a metal and/or a metal nitride.

In some embodiments, the semiconductor device may be a multi-bridge-channel field-effect transistor (MBCFET) including the semiconductor patterns 124 spaced apart from each other in the third direction D3 and serving as channels, respectively.

As illustrated above, the first spacer 200 and the second spacer 205 may be sequentially disposed on the sidewall of the lower portion the gate structure 300 in the first direction D1. The second spacer 205 may include an undoped semiconductor material, so that the second spacer 205 may reduce leakage current between the gate structure 300 and the source/drain layer 220 compared to when having the first spacer 200 alone.

In some embodiments, when forming the first epitaxial pattern 210 including a semiconductor material, a selective epitaxial growth (SEG) process may be performed on a continuous surface using not only the sidewalls of the semiconductor patterns 124 and the upper surface of the active pattern 105, but also the outer sidewall of the second spacer 205 as a seed layer. Thus, when compared to performing the SEG process using only the sidewalls of the semiconductor patterns 124 and the upper surface of the active pattern 105 as a seed layer, the semiconductor material included in the first epitaxial pattern 210 may have continuous crystallinity (i.e., may have a continuous crystal structure), and the semiconductor device including the first epitaxial pattern 210 may have improved electrical characteristics. For example, in some embodiments, the second spacer 205 may include substantially the same material as the active pattern 105 and/or the semiconductor patterns 124.

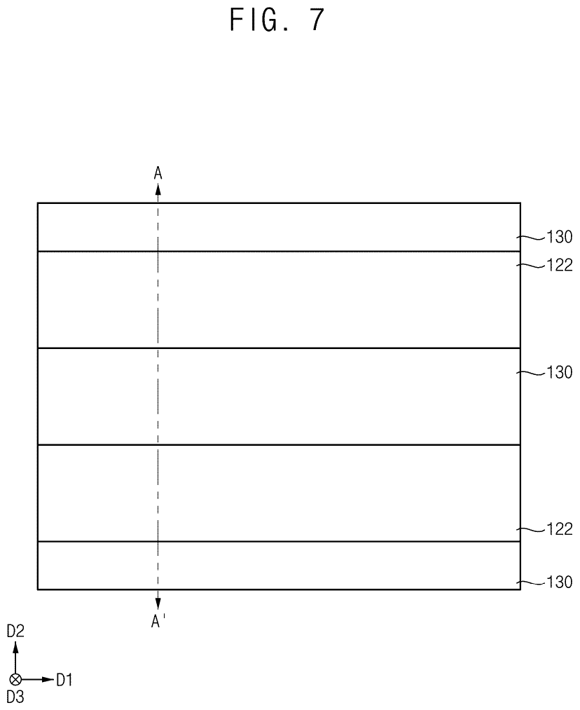

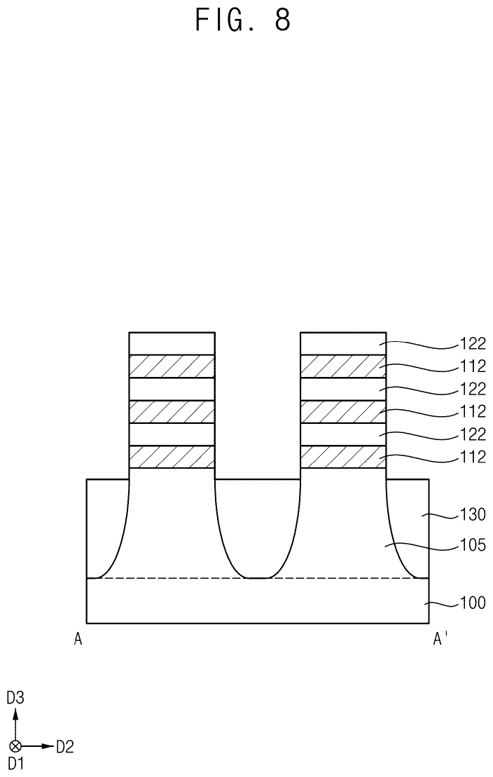

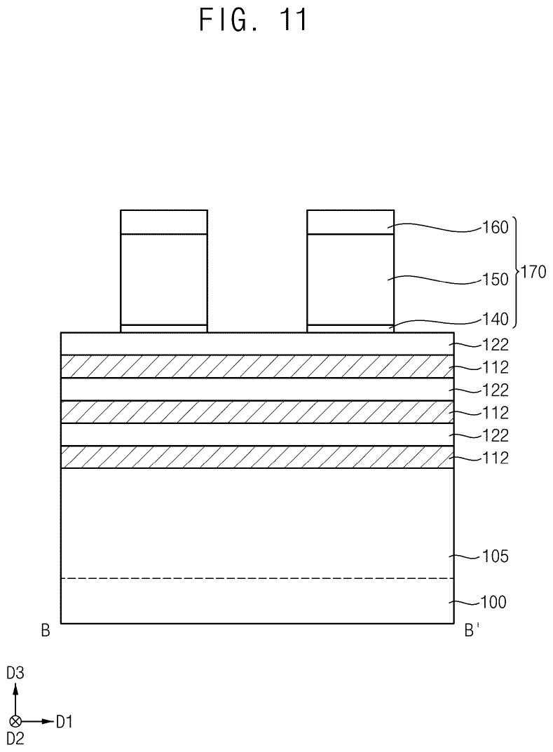

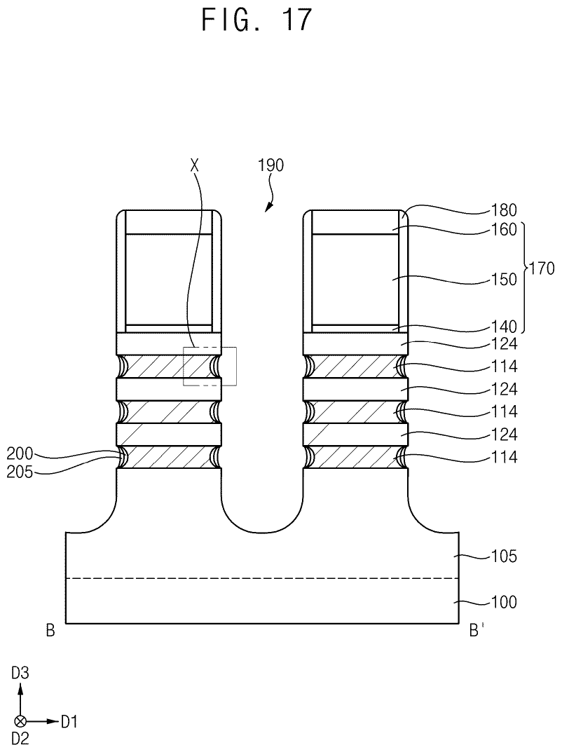

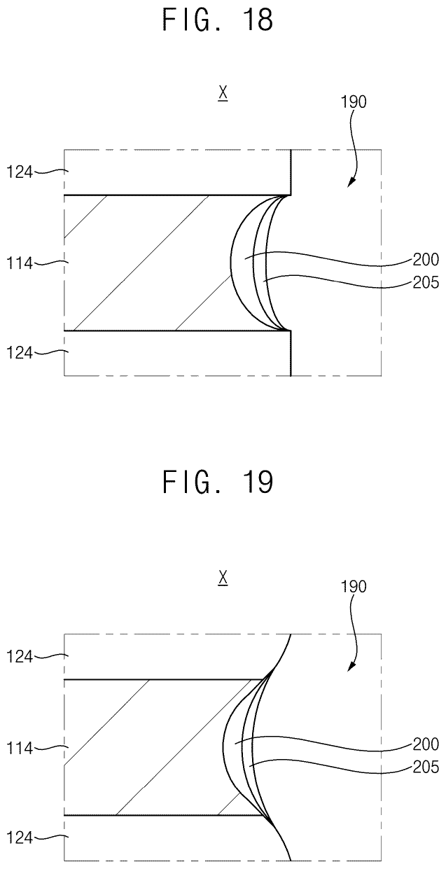

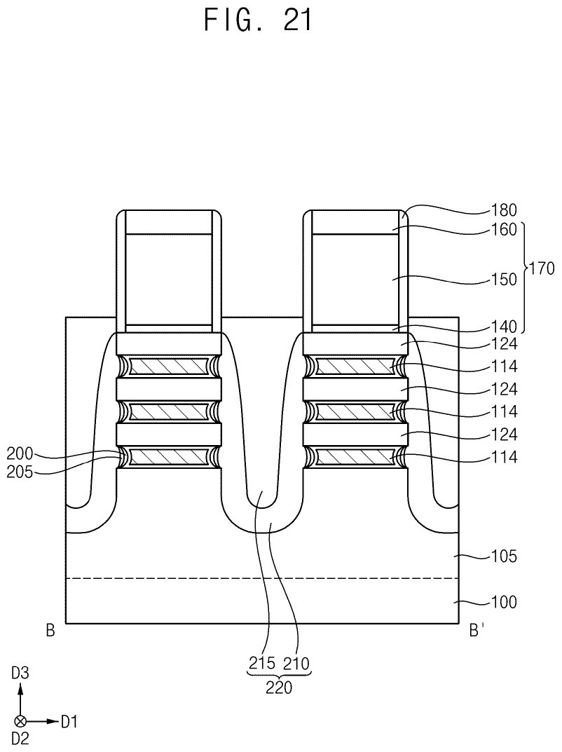

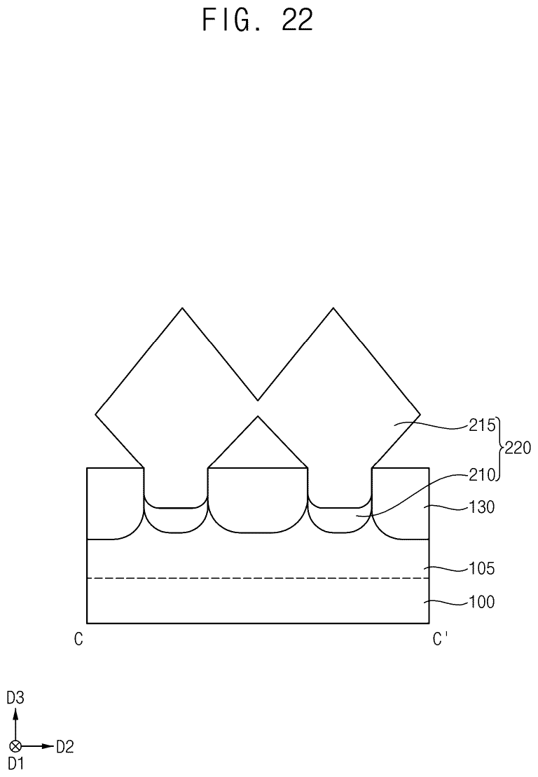

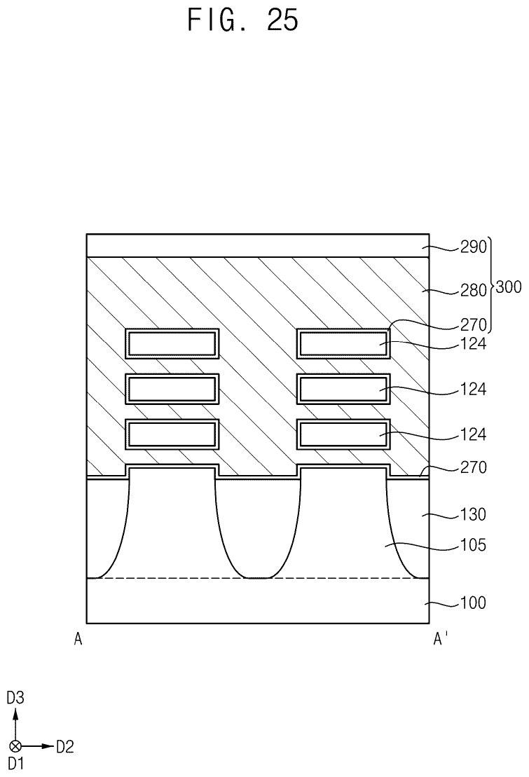

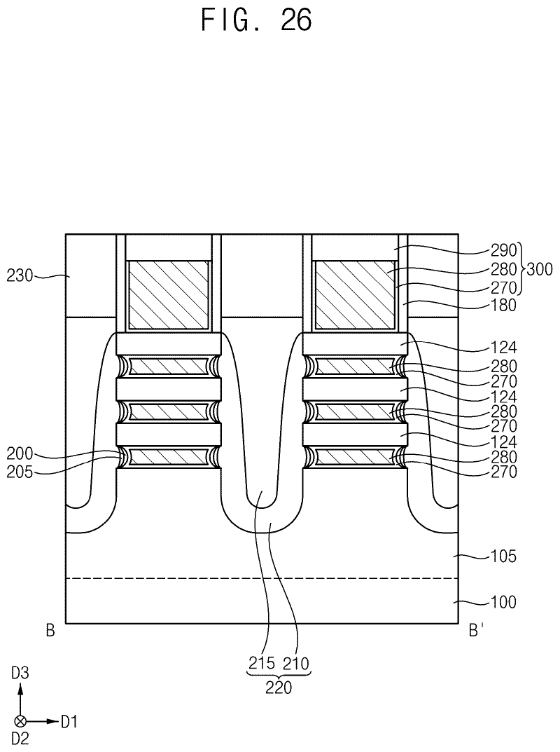

FIGS. 7 to 26 are plan views and cross-sectional views illustrating a method of manufacturing a semiconductor device in accordance with example embodiments. Particularly, FIGS. 7, 9, 20 and 24 are the plan views, and FIGS. 8, 10-19, 21-23 and 25-26 are the cross-sectional views. FIGS. 8, 10 and 25 are cross-sectional views taken along lines A-A′ of corresponding plan views, respectively. FIGS. 11-17, 21, 23 and 26 are cross-sectional views taken along lines B-B′ of corresponding plan views, respectively. FIGS. 18 and 19 are enlarged cross-sectional views of a region X of FIG. 17. FIG. 22 is a cross-sectional view taken along line C-C′ of a corresponding plan view.

Referring to FIGS. 7 and 8, a first sacrificial layer and a semiconductor layer may be alternately and repeatedly stacked on a substrate 100, a first etching mask extending in the first direction D1 may be formed on an uppermost one of the semiconductor layers, and the semiconductor layers, the first sacrificial layers and an upper portion of the substrate 100 may be etched using the first etching mask.

Thus, an active pattern 105 extending in the first direction D1 may be formed on the substrate 100, and a fin structure including sacrificial lines 112 and semiconductor lines 122 alternately and repeatedly stacked in the third direction D3 may be formed on the active pattern 105. In example embodiments, the fin structure may extend in the first direction D1, and a plurality of fin structures may be spaced apart from each other in the second direction D2 on the substrate 100.

FIG. 8 shows three sacrificial lines 112 and three semiconductor lines 122 at three levels, respectively, however, the present disclosure is not limited thereto. The semiconductor lines 122 may include, e.g., silicon, and the sacrificial lines 112 may include a material having an etching selectivity with respect to the substrate 100 and the semiconductor lines 122, e.g., silicon-germanium.

An isolation pattern 130 may be formed on the substrate 100 to be on (e.g., to cover and/or overlap) a sidewall of the active pattern 105.

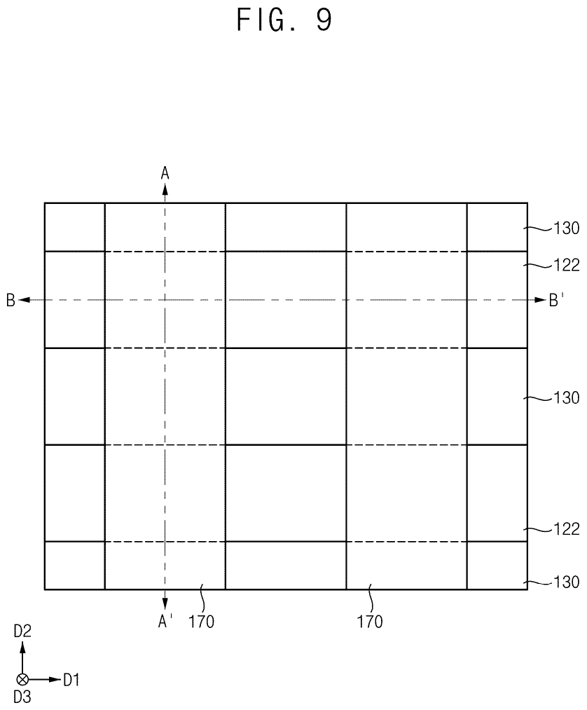

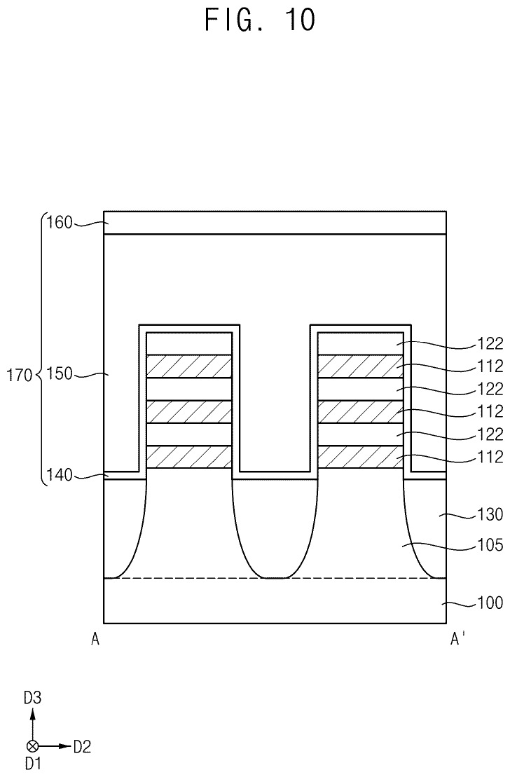

Referring to FIGS. 9 to 11, a dummy gate insulation layer, a dummy gate electrode layer and a dummy gate mask layer may be sequentially formed on the substrate 100 to be on (e.g., to cover and/or overlap) the fin structure and the isolation pattern 130, a second etching mask extending in the second direction D2 may be formed on the dummy gate mask layer, and the dummy gate mask layer may be etched using the second etching mask to form a dummy gate mask 160 on the substrate 100.

The dummy gate electrode layer and the dummy gate insulation layer may be etched using the dummy gate mask 160 as an etching mask to form a dummy gate electrode 150 and a dummy gate insulation pattern 140, respectively, on the substrate 100.

The dummy gate insulation pattern 140, the dummy gate electrode 150 and the dummy gate mask 160 sequentially stacked in the third direction D3 on the active pattern 105 and a portion of the isolation pattern 130 adjacent thereto may collectively form a dummy gate structure 170.

In example embodiments, the dummy gate structure 170 may extend in the second direction D2 on the fin structure and the isolation pattern 130, and may be on (e.g., may cover and/or overlap) an upper surface and opposite sidewalls in the second direction D2 of the fin structure.

In example embodiments, a plurality of dummy gate structures 170 may be spaced apart from each other in the first direction D1.

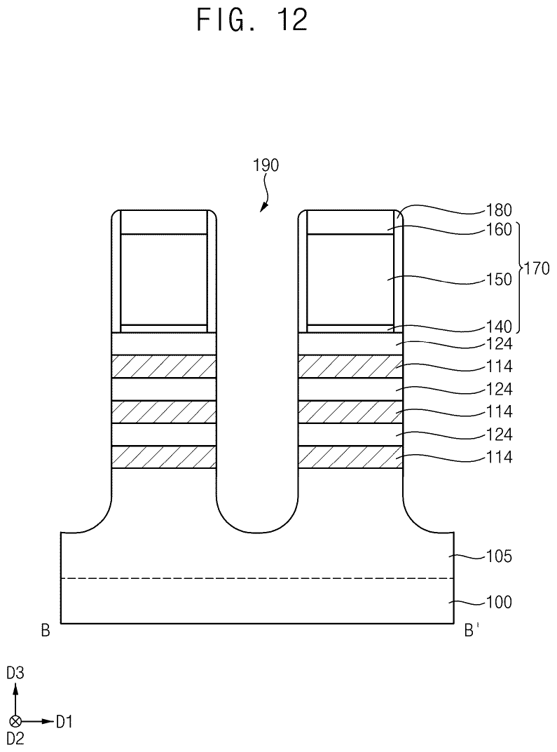

Referring to FIG. 12, a gate spacer 180 may be formed on a sidewall of the dummy gate structure 170.

Particularly, a gate spacer layer may be formed on the substrate 100 having the fin structure, the isolation pattern 130 and the dummy gate structure 170 thereon, and the gate spacer layer may be anisotropically etched to form the gate spacer 180 on (e.g., covering and/or overlapping) each of opposite sidewalls in the first direction D1 of the dummy gate structure 170.

The fin structure and an upper portion of the active pattern 105 may be etched using the dummy gate structure 170 and the gate spacer 180 as an etching mask to form a first opening 190.

Thus, the sacrificial lines 112 and the semiconductor lines 122 under the dummy gate structure 170 and the gate spacer 180 may be transformed into sacrificial patterns 114 and semiconductor patterns 124, respectively, and the fin structure extending in the first direction D1 may be divided into a plurality of parts spaced apart from each other in the first direction D1.

Hereinafter, the dummy gate structure 170, the gate spacers 180 on opposite sidewalls of the dummy gate structure 170 in the first direction D1 and the fin structure may collectively be referred to as a stack structure. In example embodiments, the stack structure may extend in the second direction D2, and a plurality of stack structures may be spaced apart from each other in the first direction D1.

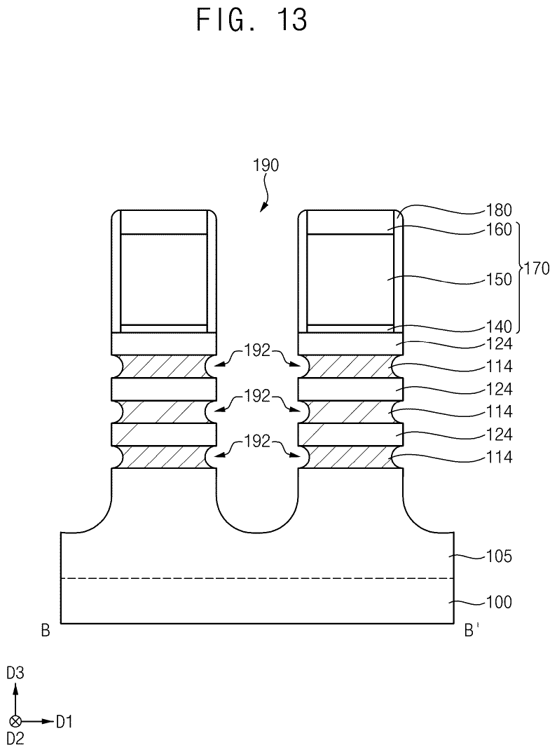

Referring to FIG. 13, a first recess 192 may be formed by etching each of opposite sidewalls in the first direction D1 of each of the sacrificial patterns 114 exposed by the first opening 190.

In example embodiments, the first recess 192 may be formed by performing a wet etching process on the sacrificial patterns 114, and the semiconductor patterns 124 may not be removed by the wet etching process. In some other embodiments, a portion of the semiconductor patterns 124 adjacent to the sacrificial patterns 114 and an upper surface of the active pattern 105 may also be partially removed by the wet etching process.

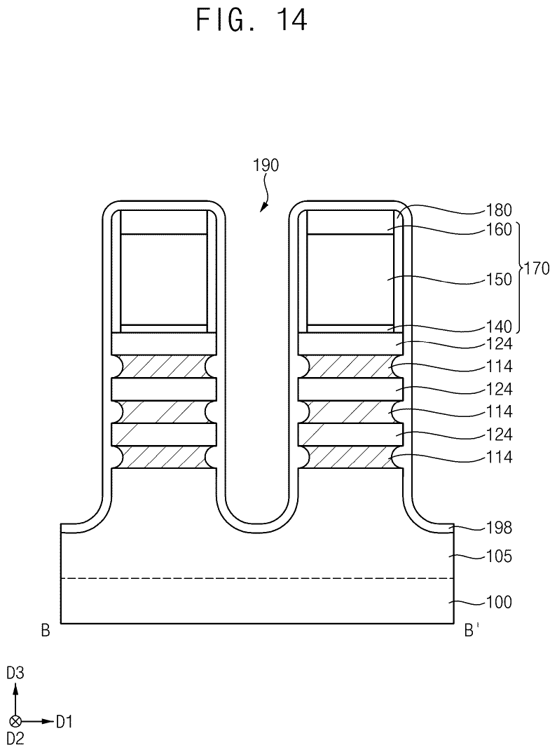

Referring to FIG. 14, a first spacer layer 198 may be formed on the sidewalls of the semiconductor patterns 124 and the sacrificial patterns 114, the upper surface of the active pattern 105, an outer sidewall and an upper surface of the gate spacer 180, and an upper surface of the dummy gate structure 170 by performing a deposition process, e.g., a chemical vapor deposition (CVD) process, an atomic layer deposition (ALD) process, etc., to be in (e.g., to fill) the first recess 192 (see FIG. 13).

In example embodiments, the first spacer layer 198 may include an insulating material, e.g., silicon nitride or silicon oxide.

In example embodiments, the first spacer layer 198 may be formed conformally and may be formed to have a thickness to sufficiently fill the first recess 192. Thus, a portion of the first spacer layer 198 on the sidewalls of the semiconductor patterns 124 and the sacrificial patterns 114 in the first direction D1 may have a smooth surface regardless of a shape of the sidewalls of the sacrificial patterns 114.

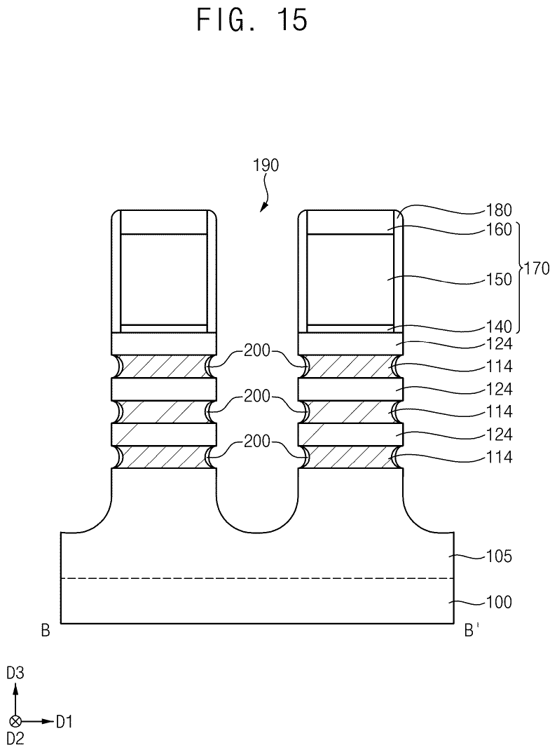

Referring to FIG. 15, a wet etching process using, e.g., phosphoric acid as an etchant may be performed on the first spacer layer 198, and thus a first spacer 200 may be formed in the first recess 192 (see FIG. 13).

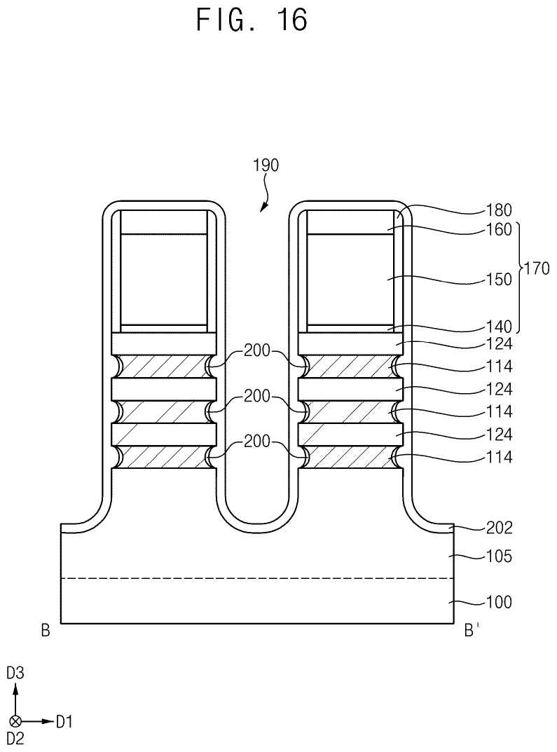

Referring to FIG. 16, a second spacer layer 202 may be formed on the sidewalls of the semiconductor patterns 124, the upper surface of the active pattern 105, an outer sidewall of the first spacer 200, the outer sidewall and the upper surface of the gate spacer 180, and the upper surface of the dummy gate structure 170 by performing a deposition process, e.g., a chemical vapor deposition (CVD) process, an atomic layer deposition (ALD) process, etc.

In example embodiments, the second spacer layer 202 may include a semiconductor material, e.g., silicon or silicon-germanium, and the semiconductor material may be in an amorphous state.

Referring to FIGS. 17 to 19, a second spacer 205 may be formed on the outer sidewall of the first spacer 200 by performing an etching process on the second spacer layer 202 (see FIG. 16).

In example embodiments, the wet etching process may be performed using a diluted ammonia mixture as an etchant.

In some embodiments, as illustrated in FIG. 18, each of the first spacer 200 and the second spacer 205 may be formed between the semiconductor patterns 124 adjacent to each other in the third direction D3 and between a lowermost one of semiconductor patterns 124 and the upper surface of the active pattern 105, and thus may not overlap the semiconductor patterns 124 and the active pattern 105 in the first direction D1.

In other embodiments, as illustrated in FIG. 19, each of the first spacer 200 and the second spacer 205 may be formed on the sidewall of the sacrificial pattern 114 and a portion of the sidewall of each of the semiconductor patterns 124, or on the upper surface of the active pattern 105 adjacent to the sidewall of the sacrificial pattern 114 in the third direction D3, and may thus partially overlap the semiconductor patterns 124 and the upper surface of the active pattern 105 in the first direction D1.

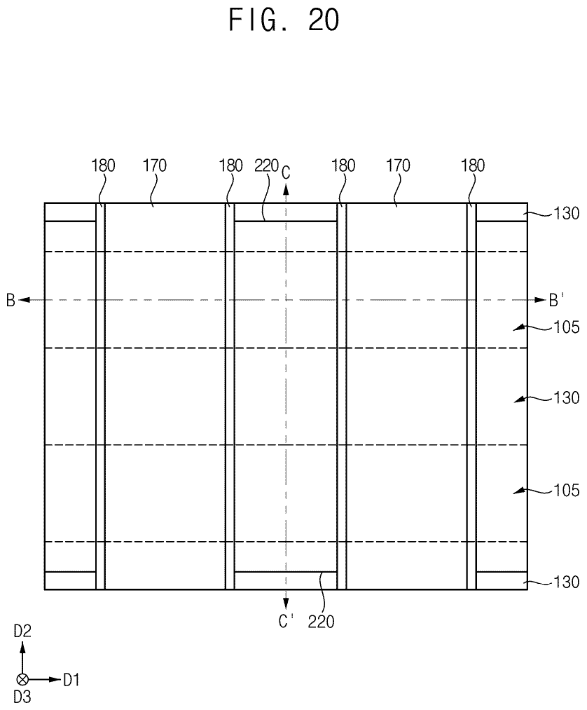

Referring to FIGS. 20 to 22, a first selective epitaxial growth (SEG) process may be performed using the sidewalls of the semiconductor patterns 124, the outer sidewall of the second spacer 205 and the upper surface of the active pattern 105 exposed by the first opening 190 (see FIGS. 17 to 19) as a seed layer to form a first epitaxial pattern 210 in the first opening 190. For example, in some embodiments, the second spacer 205 may include substantially the same material as the active pattern 105 and/or the semiconductor patterns 124.

In example embodiments, the first SEG process may be performed using a silicon source gas, e.g., dichlorosilane (SiH₂Cl₂) gas and a germanium source gas, e.g., germanium tetrahydride (GeH₄) gas, and thus the first epitaxial pattern 210 may be formed to include single crystalline silicon-germanium (SiGe). As another example, the first SEG process may be performed using a p-type impurity source gas, e.g., diborane (B₂H₆) gas, together with the silicon source gas and the germanium source gas, and thus the first epitaxial pattern 210 may be formed to include single crystalline silicon-germanium (SiGe) doped with p-type impurities. For example, the first epitaxial pattern 210 may have a first p-type impurity concentration.

In other embodiments, the first SEG process may be performed using a silicon source gas, e.g., disilane (Si₂H₆) gas, and thus the first epitaxial pattern 210 may be formed to include single crystalline silicon. As another example, the first SEG process may be performed using an n-type impurity source gas, e.g., phosphine (PH₃) gas, together with the silicon source gas, and thus the first epitaxial pattern 210 may be formed to include single crystalline silicon doped with n-type impurities. For example, the first epitaxial pattern 210 may have a first n-type impurity concentration.

A second SEG process may be performed using an inner sidewall of the first epitaxial pattern 210 as a seed layer, to form a second epitaxial pattern 215. In some embodiments, the first SEG process and the second SEG process may be performed in-situ.

In example embodiments, the second SEG process may be performed using a silicon source gas, e.g., disilane (Si₂H₆) gas, and a germanium source gas, e.g., germanium tetrahydride (GeH₄) gas, together with a p-type impurity source gas, e.g., diborane (B₂H₆) gas, and thus the second epitaxial pattern 215 may be formed to include single crystalline silicon-germanium (SiGe) doped with p-type impurities. For example, the second epitaxial pattern 215 may have a second p-type impurity concentration higher than the first p-type impurity concentration of the first epitaxial pattern 210.

In other embodiments, the second SEG process may be performed using a silicon source gas, e.g., disilane (Si₂H₆) gas, together with an n-type impurity source gas, e.g., phosphine (PH₃) gas, and thus the second epitaxial pattern 215 may be formed to include single crystalline silicon layer doped with n-type impurities. For example, the second epitaxial pattern 215 may have a second n-type impurity concentration higher than the first n-type impurity concentration of the first epitaxial pattern 210.

The first and second epitaxial patterns 210 and 215 may collectively form a source/drain layer 220.

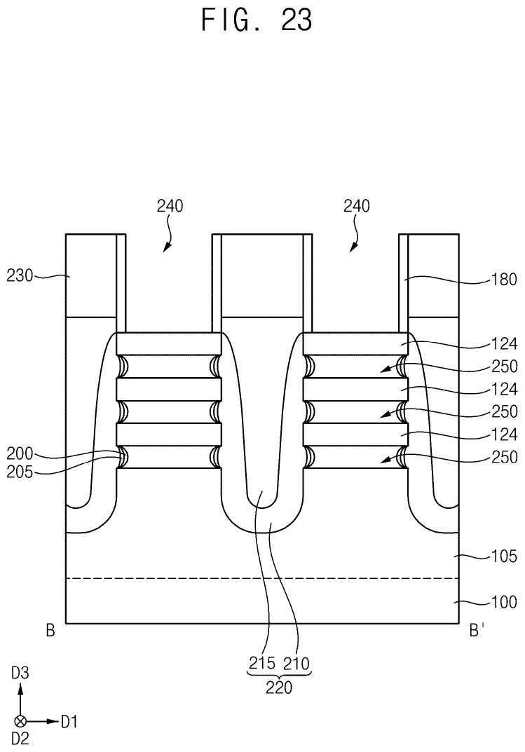

Referring to FIG. 23, a first insulating interlayer 230 may be formed on the stack structure, the source/drain layer 220 and the isolation pattern 130, and a planarization process may be performed until an upper surface of the dummy gate electrode 150 included in the stack structure is exposed to remove an upper portion of the first insulating interlayer 230 and the dummy gate mask 160 included in the dummy gate structure 170.

The exposed dummy gate electrode 150 and the dummy gate insulation pattern 140 and the sacrificial patterns 114 under the dummy gate electrode 150 may be removed by performing, e.g., a wet etching process and/or a dry etching process.

Thus, a second opening 240 exposing the inner sidewall of the gate spacer 180 and an upper surface of an uppermost one of the semiconductor patterns 124, and a third opening 250 exposing surfaces of the semiconductor patterns 124 and the upper surface of the active pattern 105 may be formed.

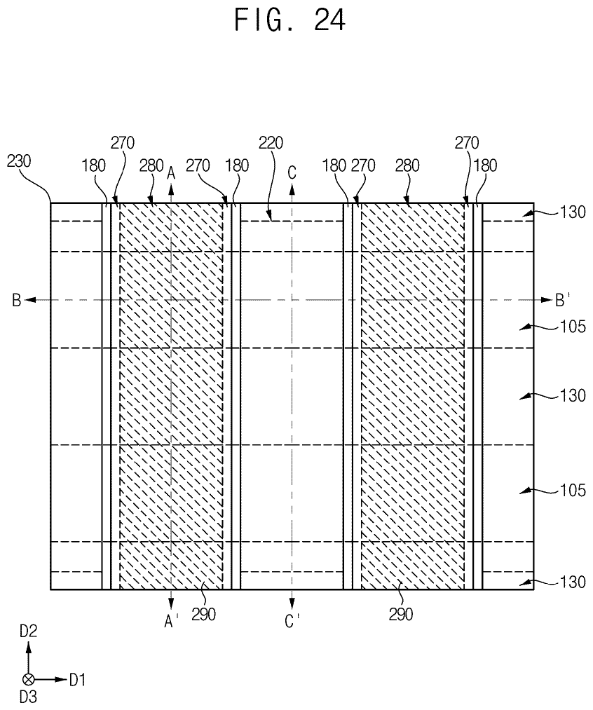

Referring to FIGS. 24 to 26, a gate insulation layer may be formed on the inner sidewall of the gate spacer 180, the surfaces of the semiconductor patterns 124, the upper surface of the active pattern 105, an upper surface of isolation pattern 130 exposed by the second and third openings 240 and 250 (see FIG. 23), and an upper surface of the first insulating interlayer 230, and a gate electrode layer may be formed to be in (e.g., to fill) a remaining portion of the second and third openings 240 and 250 on the gate insulation layer.

A planarization process may be performed on the gate electrode layer and the gate insulation layer until the upper surface of the first insulating interlayer 230 is exposed, and thus, a gate electrode 280 and a gate insulation pattern 270 may be formed in the second and third openings 240 and 250.

Upper portions of the gate insulation pattern 270 and the gate electrode 280 may be removed to form a second recess, and a capping pattern 290 may be formed in the second recess. Thus, a gate structure 300 including the gate insulation pattern 270, the gate electrode 280 and the capping pattern 290 may be formed.

Referring back to FIGS. 1 to 6, a first contact plug 370 extending into (e.g., extending through) the first insulating interlayer 230 and contacting an upper portion of the source/drain layer 220 may be formed, a second insulating interlayer 380 may be formed on the first insulating interlayer 230, the first contact plug 370, the gate spacer 180 and the gate structure 300, an etching process may be performed to partially remove the second insulating interlayer 380 and the capping pattern 290 to form a fourth opening exposing an upper surface of the gate electrode 280, and the second insulating interlayer 380 may be partially removed to form a fifth opening exposing an upper surface of the first contact plug 370.

A second contact plug 390 and a via 400 may be formed to be in (e.g., to fill) the fourth and fifth openings, respectively, and upper wirings (not shown) electrically connected to the second contact plug 390 and the via 400 may be formed. By the above processes, the semiconductor device may be manufactured.

As described above, the first opening 190 exposing the sidewalls of the semiconductor patterns 124 and the sacrificial patterns 114, and the upper surface of the active pattern 105 may be formed, an etching process may be performed to partially remove the sacrificial patterns 114 exposed by the first opening 190 to form the first recesses 192, and the first spacers 200 including an insulating material and the second spacers 205 including a semiconductor material may be formed in the first recesses 192. The SEG process using the sidewalls of the semiconductor patterns 124, the sidewalls of the second spacers 205, and the upper surface of the active pattern 105 as a seed layer may be performed to form the first epitaxial pattern 210.

If the SEG process is performed without the second spacer 205, the first spacer 200 including an insulating material may not be used as a seed layer for the SEG process, so that only the sidewalls of the semiconductor patterns 124 and the upper surface of the active pattern 105 including the semiconductor material may be used as a seed layer in the SEG process. Thus, epitaxial growth may not occur on the sidewall of the first spacer 200 and may proceed in an island shape, so that crystal structures of the semiconductor material may be mismatched at a region where the islands meet each other. As a result, the semiconductor material included in the first epitaxial pattern 210 formed by the SEG process may have a discontinuous crystal structure.

However, in example embodiments, the SEG process may be performed using the second spacers 205 as well as the sidewalls of the semiconductor patterns 124 and the upper surface of the active pattern 105 as a seed layer, and thus the epitaxial growth may be performed on a continuous surface, so that the semiconductor material included in the first epitaxial pattern 210 formed by the SEG process may have a continuous crystal structure. As a result, the semiconductor device including the first epitaxial pattern 210 may have improved electrical performance.

The foregoing is illustrative of example embodiments and is not to be construed as limiting thereof. Although some example embodiments have been described, those skilled in the art will readily appreciate that many modifications are possible to the example embodiments without departing from the scope of the present disclosure. Accordingly, all such modifications are intended to be included within the scope of the present disclosure as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a gate structure;
a plurality of channel patterns spaced apart from each other in a first direction, each of the plurality of channel patterns extending through the gate structure in a second direction substantially perpendicular to the first direction;
a source/drain layer adjacent to the gate structure in the second direction, the source/drain layer contacting the plurality of channel patterns;
a first spacer on a sidewall of the gate structure in the second direction and including an insulating material; and
a second spacer on a sidewall of the first spacer in the second direction, the second spacer contacting the source/drain layer,
wherein the first spacer includes opposite edge portions in the first direction and a center portion in the first direction, and wherein a width of the first spacer in the second direction increases from the opposite edge portions toward the center portion.

2. The semiconductor device according to claim 1, wherein the source/drain layer comprises:
a first epitaxial pattern including a first semiconductor material having a first impurity concentration; and
a second epitaxial pattern on a sidewall of the first epitaxial pattern and including a second semiconductor material having a second impurity concentration lower than the first impurity concentration.

3. The semiconductor device according to claim 2, wherein the second semiconductor material included in the second epitaxial pattern has a continuous crystal structure.

4. The semiconductor device according to claim 1, wherein the first spacer includes silicon nitride.

5. The semiconductor device according to claim 1, wherein the second spacer includes at least one of silicon or silicon-germanium.

6. The semiconductor device according to claim 5, wherein the second spacer and the plurality of channel patterns include substantially the same material.

7. The semiconductor device according to claim 1, wherein the sidewall of the first spacer is a first sidewall,
wherein the first spacer includes a second sidewall opposite to the first sidewall of the first spacer in the second direction, and
wherein the first sidewall and the second sidewall of the first spacer are both convex toward the gate structure.

8. The semiconductor device according to claim 7, wherein the first sidewall of the first spacer has a first curvature, and the second sidewall of the first spacer has a second curvature greater than the first curvature.

9. The semiconductor device according to claim 7, wherein:
the second spacer includes a first sidewall and a second sidewall opposite to each other in the second direction,
the first sidewall of the second spacer contacts the first sidewall of the first spacer, and
the second sidewall of the second spacer contacts the source/drain layer.

10. The semiconductor device according to claim 9, wherein the first sidewall and the second sidewall of the second spacer are both convex toward the gate structure.

11. The semiconductor device according to claim 1, wherein the first spacer is one of a plurality of first spacers that are spaced apart from each other in the first direction, and
wherein the second spacer is one of a plurality of second spacers that are spaced apart from each other in the first direction and are respectively adjacent to the plurality of first spacers.

12. The semiconductor device according to claim 11, wherein the source/drain layer includes protrusions that each protrude in the second direction and are spaced apart from each other in the first direction, and
wherein the protrusions of the source/drain layer respectively contact sidewalls of the plurality of second spacers.

13. A semiconductor device comprising:
a plurality of channel patterns each extending in a first direction and spaced apart from each other in a second direction substantially perpendicular to the first direction;
a gate structure at least partially surrounding an upper surface, a lower surface and a sidewall of each of the plurality of channel patterns;
a source/drain layer adjacent to the gate structure in the first direction, the source/drain layer contacting the plurality of channel patterns; and
a first spacer and a second spacer sequentially stacked on a sidewall of the gate structure in the first direction,
wherein the second spacer at least partially overlaps a first one of the plurality of channel patterns in the first direction.

14. The semiconductor device according to claim 13, wherein the first spacer includes silicon nitride, and
wherein the second spacer includes a semiconductor material.

15. The semiconductor device according to claim 13, wherein an end portion of the first spacer in the second direction contacts the first one of the plurality of channel patterns.

16. The semiconductor device according to claim 13, wherein, in a cross-sectional view, each of the first and second spacers has a crescent shape that is convex toward the gate structure.

17. A semiconductor device comprising:
an active pattern on a substrate, the active pattern extending in a first direction substantially parallel to an upper surface of the substrate;
a gate structure on the active pattern, the gate structure extending in a second direction substantially parallel to the upper surface of the substrate and crossing the first direction;
a plurality of channel patterns spaced apart from each other in a vertical direction substantially perpendicular to the upper surface of the substrate, each of the plurality of channel patterns extending through the gate structure;
a source/drain layer comprising:
a first epitaxial pattern adjacent to the gate structure in the first direction, the first epitaxial pattern including a first semiconductor material having a first impurity concentration; and
a second epitaxial pattern contacting a sidewall of the first epitaxial pattern, the second epitaxial pattern including a second semiconductor material having a continuous crystal structure and having a second impurity concentration lower than the first impurity concentration;
a first spacer on a sidewall of the gate structure in the first direction and including silicon nitride; and
a second spacer on a sidewall of the first spacer in the first direction and including a semiconductor material.

18. The semiconductor device according to claim 17, wherein the second epitaxial pattern includes protrusions that each protrude in the first direction and are spaced apart from each other in the vertical direction, and
wherein at least one of the protrusions of the second epitaxial pattern contacts a sidewall of the second spacer.

19. The semiconductor device according to claim 17, wherein the second spacer includes at least one of silicon or silicon-germanium, and
wherein each of the plurality of channel patterns includes substantially the same material as that of the second spacer.

20. The semiconductor device according to claim 17, wherein, in a cross-sectional view, each of the first and second spacers has a crescent shape that is convex toward the gate structure.
